(19) United States
(12) Patent Application Publication
(10) Pub. No.: US 2024/0162191 A1
(43) Pub. Date: May 16, 2024

(54) PACKAGE SUBSTRATE WITH ALTERNATING DIELECTRIC MATERIAL LAYER PAIRS

(71) Applicant: Intel Corporation, Santa Clara, CA (US)

(72) Inventors: Jeremy Ecton, Gilbert, AZ (US); Changhua Liu, Chandle, AZ (US); Brandon C. Marin, Gilbert, AZ (US); Srinivas V. Pietambaram, Chandler, AZ (US); Mohammad Mamunur Rahman, Gilbert, AZ (US)

(73) Assignee: Intel Corporation, Santa Clara, CA (US)

(21) Appl. No.: 18/054,211

(22) Filed: Nov. 10, 2022

(51) Int. Cl. H01L 25/065; H01L 23/498; H01L 23/538; H01L 23/552

(52) U.S. Cl. CPC H01L 25/0655; H01L 23/49894; H01L 23/5381; H01L 23/5383; H01L 23/5384; H01L 23/552; H01L 24/16; H01L 2224/16225

(57) ABSTRACT

Embodiments of a package substrate includes: a conductive via in a first layer, the first layer comprising a positive-type photo-imageable dielectric; a conductive trace in a second layer, the second layer comprising a negative-type photo-imageable dielectric; and an insulative material between the first layer and the second layer, the insulative material configured to absorb electromagnetic radiation in a wavelength range between 10 nanometers and 800 nanometers. The conductive via is directly attached to the conductive trace through the insulative material, the positive-type photo-imageable dielectric is soluble in a photoresist developer upon exposure to the electromagnetic radiation, and the negative-type photo-imageable dielectric is insoluble in the photoresist developer upon exposure to the electromagnetic radiation.

### TECHNICAL FIELD

The present disclosure relates to techniques, methods, and apparatus directed to a package substrate with alternating dielectric material layer pairs.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic cross-sectional view of an example microelectronic assembly according to some embodiments of the present disclosure.

FIG. 2A is a schematic plan view of a portion of a microelectronic assembly according to some embodiments of the present disclosure.

FIG. 2B is a schematic cross-sectional view of the portion of microelectronic assembly of FIG. 2A.

FIGS. 3A-3P are schematic cross-sectional and perspective views of a portion of a microelectronic assembly at various stages of manufacture according to some embodiments of the present disclosure.

FIG. 3Q is a schematic plan view of the portion of a microelectronic assembly of FIG. 3P.

FIGS. 4A-4C are schematic cross-sectional views of a portion of a microelectronic assembly at various stages of manufacture according to some embodiments of the present disclosure.

FIG. 5 is a cross-sectional view of a device package that includes one or more microelectronic assemblies in accordance with any of the embodiments disclosed herein.

FIG. 6 is a cross-sectional side view of a device assembly that includes one or more microelectronic assemblies in accordance with any of the embodiments disclosed herein.

FIG. 7 is a block diagram of an example computing device that includes one or more microelectronic assemblies in accordance with any of the embodiments disclosed herein.

### DETAILED DESCRIPTION

### Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

The demand for miniaturization of form factor and increased levels of integration for high performance are driving sophisticated packaging approaches in the semiconductor industry. Advances in semiconductor processing and logic design have permitted an increase in the amount of logic circuits that may be included in processors and other IC devices. As a result, many processors now have multiple cores that are monolithically integrated on a single die. Generally, these types of monolithic ICs are also described as planar since they take the form of a flat surface and are typically built on a single silicon wafer made from a monocrystalline silicon boule. The typical manufacturing process for such monolithic ICs is called a planar process, allowing photolithography, etching, heat diffusion, oxidation, and other such processes to occur on the surface of the wafer, such that active circuit elements (e.g., transistors and diodes) are formed on the planar surface of the silicon wafer.

Current technologies permit hundreds and thousands of such active circuit elements to be formed on a single die so that numerous logic circuits may be enabled thereon. In such monolithic dies, the manufacturing process must be optimized for all the circuits equally, resulting in trade-offs between different circuits. In addition, because of the limitation of having to place circuits on a planar surface, some circuits are farther apart from some others, resulting in decreased performance such as longer delays. The manufacturing yield may also be severely impacted because the entire die may have to be discarded if even one circuit is malfunctional.

One solution to overcome such negative impacts of monolithic dies is to disaggregate the circuits into smaller dies (e.g., chiplets, tiles) electrically coupled by interconnect bridges. The smaller dies are part of an assembly of interconnected dies that together form a complete IC in terms of application and/or functionality, such as a memory chip, microprocessor, microcontroller, commodity IC (e.g., chip used for repetitive processing routines, simple tasks, application specific IC, etc.), and system-on-a-chip (SOC). In other words, the individual dies are connected to create the functionalities of a monolithic IC. By using separate dies, each individual die can be designed and manufactured optimally for a particular functionality. For example, a processor core that contains logic circuits might aim for performance, and thus might require a very speed-optimized layout; this has different manufacturing requirements compared to a USB controller, which is built to meet certain USB standards, rather than for processing speed; by having different parts of the overall design separated into different dies, each one optimized in terms of design and manufacturing, the overall yield and cost of the combined die solution may be improved.

The connectivity between these dies is achievable by many ways. For example, in 2.5D packaging solutions, a silicon interposer and through-silicon vias (TSVs) connect dies at silicon interconnect speed in a minimal footprint. In another example, a silicon bridge embedded under the edges of two interconnecting dies facilitates electrical coupling between them. The bridge die may be embedded in an organic interposer, which allows for top-packaged chips to communicate with other chips horizontally using the bridge die and vertically, using Through-Mold Vias (TMVs) in the interposer. Such die partitioning enables miniaturization of small form factor and high performance without yield issues seen with other methods but needs fine die-to-die interconnections. The bridge die can facilitate such high-density interconnections by inserting the bridge dies only where needed. Standard flip-chip assembly is used for robust power delivery and to connect high-speed signals directly from chip to the package substrate.

For future generations of die partitioning, several bridges that can connect the dies at fine bump pitches (e.g., 25 microns or lower) than that are possible in current technologies are needed. In many packages with bridge dies, high cumulative Bump Thickness Variation (BTV) from the nature of organic dielectric materials used in the package substrate can make such fine bump pitches prohibitively expensive to manufacture due to low yields. In addition, connecting the bridge die to the overlying silicon dies through a stacked via configuration as is typical in current packages results in significant stresses at the via locations. The significant stresses on the vias can potentially result in a via crack, which is a significant reliability risk. By adopting a via staggering configuration wherein the vias are routed with an offset relative to the layer below and above a given patterning layer, the stresses can be significantly reduced as the staggering configuration acts as a cantilever to absorb stresses and reduce the likelihood of via cracking.

However, via staggering is ultimately limited by patterning resolution and overlay alignment error. Historically, there have been two key metrics driving lithography: on product overlay (also known as overlay alignment), and critical dimension uniformity. Both these metrics are monitored to reduce and eliminate edge placement error (EPE) (also called “overlay alignment error”). EPE is the difference between the intended and the printed features of a layout containing features, such as vias, in precise locations. Many variables feed into the EPE metric, including optical proximity correction, reticle manufacture errors, resist, expose, develop, on product overlay, critical dimension uniformity, line width roughness and post lithography processing such as etching.

Under such conventional lithography approaches, scaling from 25 micrometers bump pitch to 18 micrometers bump pitch pushes the via staggering design rules beyond existing capabilities of current lithography tools and materials. In particular, the overlay alignment error required to accommodate 25 micrometers bump pitch for a via diameter of 4 micrometers, for example, is less than 2 micrometers, with an additional 5 micrometers plane-to-plane patterning resolution to guarantee no overlap of vias (i.e., stacked via type configuration). Reducing the via diameter below 4 micrometers to alleviate the overlay alignment error is considered high risk to small via dimension and less resilient to stresses. Reducing the bump pitch further to 18 micrometers is considerably more challenging and would require a significant reduction in patterning resolution and/or overlay alignment error and/or via diameter to accommodate the tighter design rules, which is considered high risk in terms of process capability and/or via reliability.

In some techniques, via-pads are used to align vias onto conductive traces. Such via-pads are currently formed using registration of either laser drilling or a lithographic mask defining the via to existing fiducials on a layer of the substrate in which the via pad is disposed, i.e., the pad layer. However, due to shrinkage during curing of the dielectric layer deposited on the pad layer of the substrate and shifting the pad with respect to the fiducials, the via-to-pad registration is not preserved across the field of the substrate layer. The via-to-pad misalignment may cause device failures, decrease yield and increase manufacturing cost. Additionally, the large size of the pads and the reduced via registration capability limit the density of metal lines and other components on the substrate.

One possible solution to alleviate some of the overlay alignment error is to incorporate a zero-misaligned via process. A current technique for forming zero-misaligned vias incorporates a gray-scale exposure to create local differences in exposure dose, enabling separate steps for developing and plating to create a zero-misaligned copper step or via. Yet, the process requires stringent control of dose, develop dwell time, and greyscale transmission. Additionally, such existing techniques for zero-misaligned or self-aligned vias result in an undesirable taper of the via sidewalls due to the isotropic nature of electrolytic plating. Such taper can impact the overlay budget (i.e., available space and dimensions for overlay), making smaller pitches difficult and expensive to achieve.

Accordingly, embodiments described herein enable a package substrate that includes: a conductive via in a first layer, the first layer comprising a first organic dielectric material; a conductive trace in a second layer, the second layer comprising a second organic dielectric material; and an insulative material between the first layer and the second layer, the insulative material configured to absorb electromagnetic radiation having wavelength in a range between 10 nanometers and 800 nanometers. The conductive via is directly attached to the conductive trace through the insulative material, the first organic dielectric material comprises a positive-type photo-imageable dielectric that is soluble upon exposure to the electromagnetic radiation, and the second organic dielectric material comprises a negative-type photo-imageable dielectric that is insoluble upon exposure to the electromagnetic radiation.

Some other embodiments of the package substrate comprise a plurality of different dielectric materials in separate layers; a plurality of conductive vias in a first subset of the layers; and a plurality of conductive traces in a second subset of the layers. Individual ones of the first subset of the layers alternate with individual ones of the second subset of the layers. Conductive vias in separate ones of the first subset of the layers, the conductive vias attached to a common conductive trace, are misaligned with respect to each other in a direction along a length of the conductive trace. Centers of a subset of conductive vias in a first layer in the first subset of layers are aligned with corresponding centerlines of conductive traces in a second layer in the second subset of layers, the first layer being adjacent to the second layer, the subset of conductive vias being coupled directly to the corresponding conductive traces.

Some embodiments of a microelectronic assembly comprise: a plurality of IC dies; and a package substrate coupled to the plurality of IC dies. The package substrate comprises: a bridge IC die surrounded by an epoxy-based dielectric material; conductive traces in negative-type photo-imageable dielectric; conductive vias in positive-type photo-imageable dielectric; and an insulative material capable of absorbing electromagnetic radiation having wavelength in a range between 10 nanometers and 800 nanometers at a subset of interfaces between the negative-type photo-imageable dielectric and positive-type photo-imageable dielectric.

Embodiments disclosed herein further include a method, comprising: providing a support structure; depositing a positive-type photo-imageable dielectric in a first layer over the support structure; depositing an insulative material over the positive-type photo-imageable dielectric, the insulative material being capable of absorbing electromagnetic radiation having wavelength in a range between 10 nanometers and 800 nanometers; depositing a negative-type photo-imageable dielectric in a second layer over the insulative material; forming a first trench in the negative-type photo-imageable dielectric, the first trench corresponding to a profile of a conductive trace; forming a second trench in the positive-type photo-imageable dielectric, the second trench corresponding to the conductive via; and depositing conductive material in the first trench and the second trench, forming the conductive trace and connected conductive via respectively.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may comprise a semiconductor material including, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may comprise a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In many embodiments, an FET is a four-terminal device. In silicon-on-insulator, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and PCBs such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photo-imageable polymers, dry film photo-imageable polymers, acrylics, solvents) may be provided in an IC package described herein and may not be labeled or shown to avoid cluttering the drawings.

Solder resist may be a liquid or dry film material including photo-imageable polymers. In some embodiments, solder resist may be non-photo-imageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

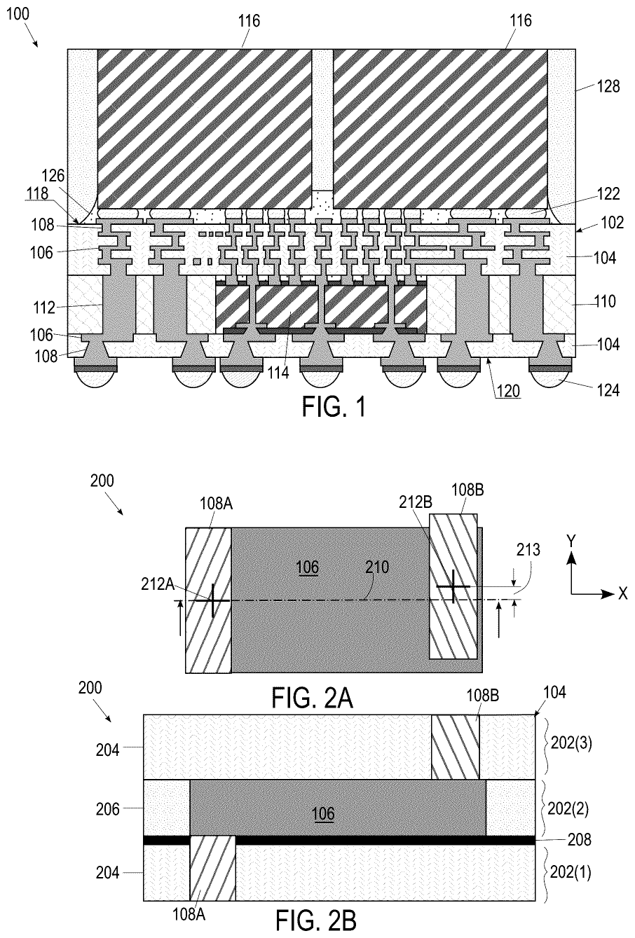

FIG. 1A is a schematic cross-sectional view of an example microelectronic assembly 100 according to some embodiments of the present disclosure. Microelectronic assembly 100 comprises a package substrate 102 comprising a plurality of layers of dielectric materials 104 and conductive traces 106 alternating with conductive vias 108 in alternate layers of dielectric material 104. In various embodiments, conductive vias 108 and conductive traces 106 comprise copper. In many embodiments, conductive vias 108 in alternating layers adjacent to a conductive trace 106 may be staggered with respect to each other (i.e., their centerlines are not aligned). In many embodiments, at least some conductive vias 108 and conductive traces 106 to which such vias 108 are attached may have zero-misalignment (i.e., they may be self-aligned). In some such embodiments, EPE of conductive via 108 relative to conductive trace 106 may be less than 0.1 micrometers. In some such embodiments, centerlines of such conductive vias 108 and conductive traces 106 may be mutually aligned. In various embodiments, sidewalls of conductive vias 108 may be orthogonal to conductive traces 106.

Package substrate 102 further comprises another organic dielectric material 110 through which conductive through-dielectric vias (TDVs) 112 are disposed. In some embodiments, organic dielectric material 110 comprises silica-filled epoxy, such as used in mold compounds. In some embodiments, a bridge IC die 114 may be embedded in organic dielectric material 110. Bridge IC die 114 may comprise TSVs in some embodiments (e.g., as shown); in other embodiments, bridge IC die 114 may not comprise TSVs.

A plurality of IC dies 116 are coupled to a first surface 118 of the package substrate by interconnects 122. Package substrate 102 comprises a second surface 120 opposite first surface 118 on which are disposed interconnects 124. In some embodiments, interconnects 122 comprise FLIs and interconnects 124 comprise SLIs as discussed in the previous subsection. In some embodiments, dielectric material 104, along with conductive traces 106 and conductive vias 108 may be disposed proximate to second surface 120 of package substrate 102. In such embodiments, organic dielectric material 110 may be in between opposing regions of dielectric material 104.

FIG. 2A shows a simplified cross-sectional view of a portion 200 of self-aligned conductive vias 108 and conductive traces 106. A portion of conductive trace 106 is coupled to staggered conductive vias 108A and 108B. In other words, conductive vias 108A and 108B coupled to common conductive trace 106 are displaced relative to each other longitudinally (e.g., along a length of conductive trace 106, along X-axis). As shown in FIG. 2B, which is a simplified cross-sectional view of portion 200 of FIG. 2A, conductive vias 108A and 108B and conductive trace 106 are in separate layers 202 of different dielectric materials 104 that are not coplanar. For example, conductive via 108A is in layer 202(1), comprising positive-type photo-imageable dielectric 204; conductive trace 106 is in layer 202(2) comprising negative-type photo-imageable dielectric 206, and conductive via 108B is in layer 202(3) comprising positive-type photo-imageable dielectric 204. Examples of positive-type photo-imageable dielectric 204 include polymethyl methacrylate (PMMA), diazoalkylquinone, diazobenzoquinone, diazonaphtoquinone with an ester backbone, which generates a photo-acid that cleaves the ester. Examples of negative-type photo-imageable dielectric 206 include epoxy-based materials, resins, and other such materials commonly known in the art.

An insulative material 208 is in between layers 202(1) and 202(2). Insulative material 208 has properties that enable it to absorb electromagnetic radiation in a wavelength range between 10 nanometers and 800 nanometers. In some embodiments, insulative material 208 can absorb visible light. In some other embodiments, insulative material 208 can absorb ultraviolet light. Examples of insulative material 208 comprises carbon black, carbon nanotubes, anti-reflective nanorods, graphene, and transferable hyperbolic metamaterial particles (THM MP).

The portion of conductive trace 106 coupled to staggered conductive vias 108A and 108B may have a centerline 210. Conductive via 108A may have a center 212A and conductive via 108B may have a center 212B. Conductive vias 108A and 108B in alternating layers 202(1) and 202(3) adjacent to layer 202(2) of conductive trace 106 are staggered with respect to each other (e.g., along X-axis), i.e., they are not mutually aligned. Thus, centers 212A and 2126 of respective conductive vias 108A and 108B are not vertically stacked one on top of another but may be displaced with respect to each other. Further, conductive via 108A and conductive trace 106 may not be separated by any interface, seam or material, a feature arising from the nature of the processing used to fabricate conductive via 108A and conductive trace 106.

In various embodiments, the spacing/pitch between adjacent conductive traces 106 or conductive vias 108 in the same layer 202 may be between approximately 1 micrometers and 3 micrometers. EPE 213 of conductive via 108A with respect to conductive trace 106 may be less than 0.1 micrometers. In some embodiments, conductive via 108B may be misaligned from its intended location by an EPE 213 that is more than 0.1 micrometers, for example, in a range between 0.1 micrometers to 1 micrometers. Thus, center 212A may be aligned with centerline 210 whereas center 2128 may not be aligned with centerline 210. The misalignment of conductive via 108B may be along the Y-axis, orthogonal to centerline 210 of conductive trace 106 in some embodiments. In some other embodiments, EPE 213 of conductive via 108B may be less than 0.1 micrometers.

The difference in misalignment of conductive vias 108A and 108B relative to conductive trace 106 may arise from the difference in photolithography processing used to fabricate conductive vias 108A and 108B. Whereas conductive via 108A may be formed by using a profile of conductive trace 106 in a mask comprising insulative material 208 to generate conductive via 108A, thus resulting in zero-misalignment, conductive via 108B may be formed using another layer of insulative material 208, the mask being aligned by fiducials independent of conductive trace 106 and thus may be subject to traditional alignment errors. The sidewalls of conductive vias 108 may be orthogonal (i.e., not tapered) to conductive trace 106 in some embodiments. In some embodiments, the width of conductive trace 106 (e.g., measured in a direction orthogonal and coplanar to the longitudinal direction) may be substantially same as the respective widths of conductive vias 108A and 108B.

Although only one conductive via 108A is shown and described as being aligned with conductive trace 106, any number of such conductive vias 108A may be provisioned along the length of conductive trace 106, all of which are self-aligned with respect to conductive trace 106 within the broad scope of the embodiments herein. All such conductive vias 108A may be in a common layer 202(1) of positive-type photo-imageable dielectric 204, adjacent to and under layer 202(2) in which conductive trace 106 is located. Further, package substrate 102 may comprise a plurality of such layers 202, without any limitation to the number of layers except for those that arise due to manufacturing or design considerations beyond the scope of the present disclosure.

In various embodiments, any of the features discussed with reference to any of FIGS. 1-2 herein may be combined with any other features to form a package with one or more IC dies as described herein. For example, in some embodiments, some of conductive vias 108A and 108B may be staggered relative to each other and other ones of conductive vias 108A and 108B may be vertically aligned. In another example, some conductive vias 108 may be formed using photolithography processes, and some other conductive vias 108 may be formed using laser drilling or other processes, in which case those conductive vias 108 formed from such non-photolithography processes may not be aligned with conductive trace 106. Some such combinations are described above, but, in various embodiments, further combinations and modifications are possible. Various different embodiments described in different figures may be combined suitably based on particular needs within the broad scope of the embodiments.

Example Methods

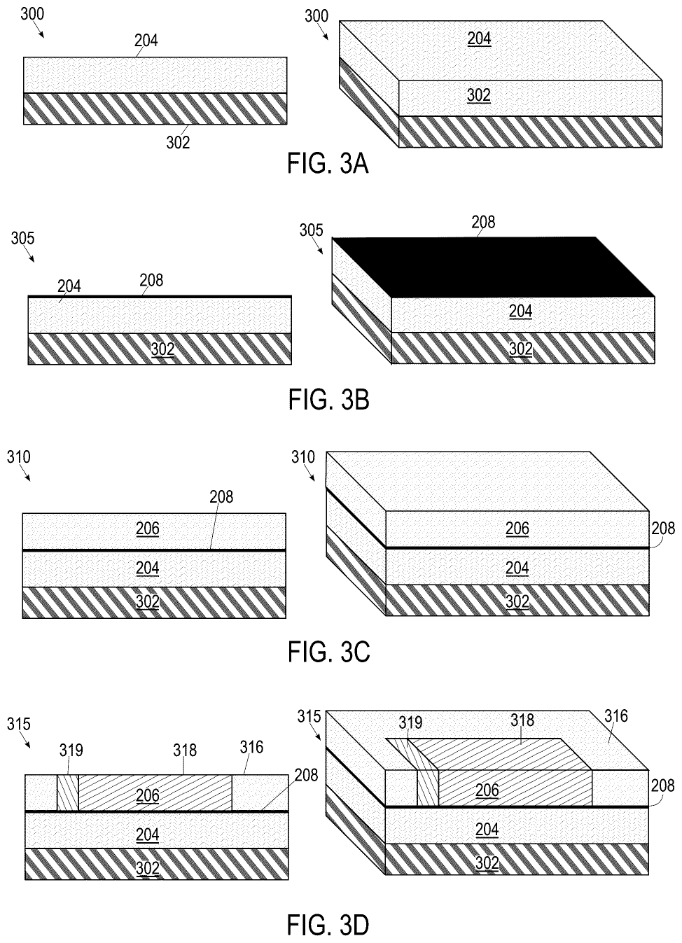

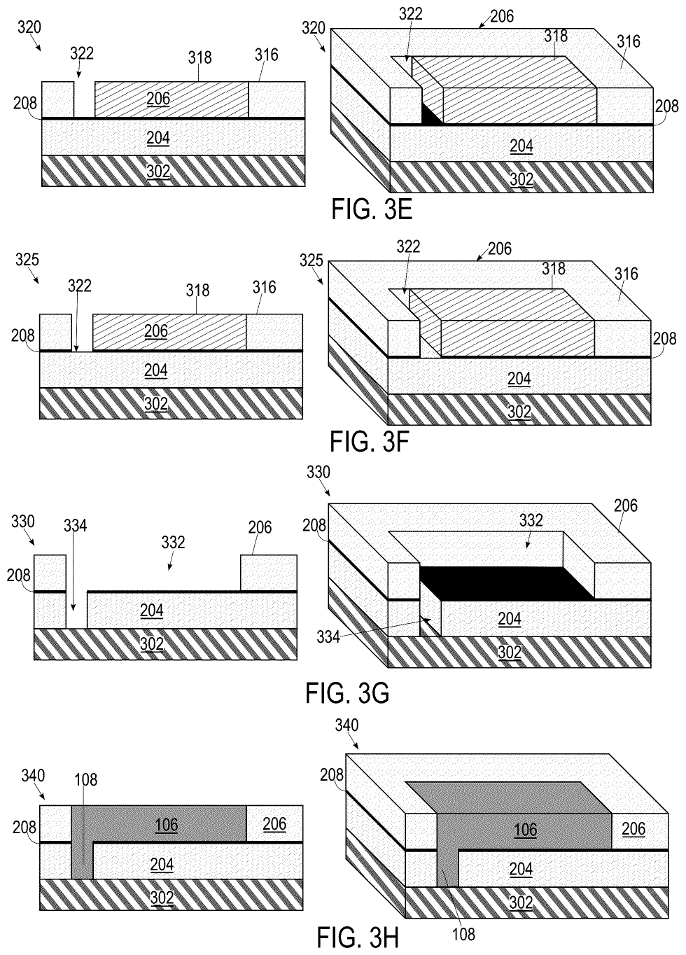

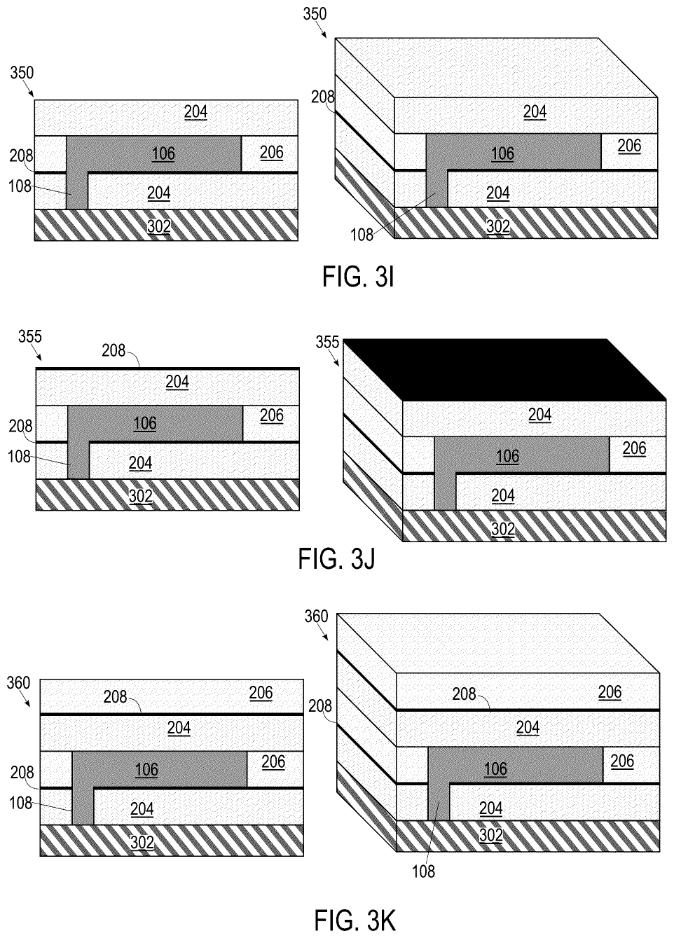

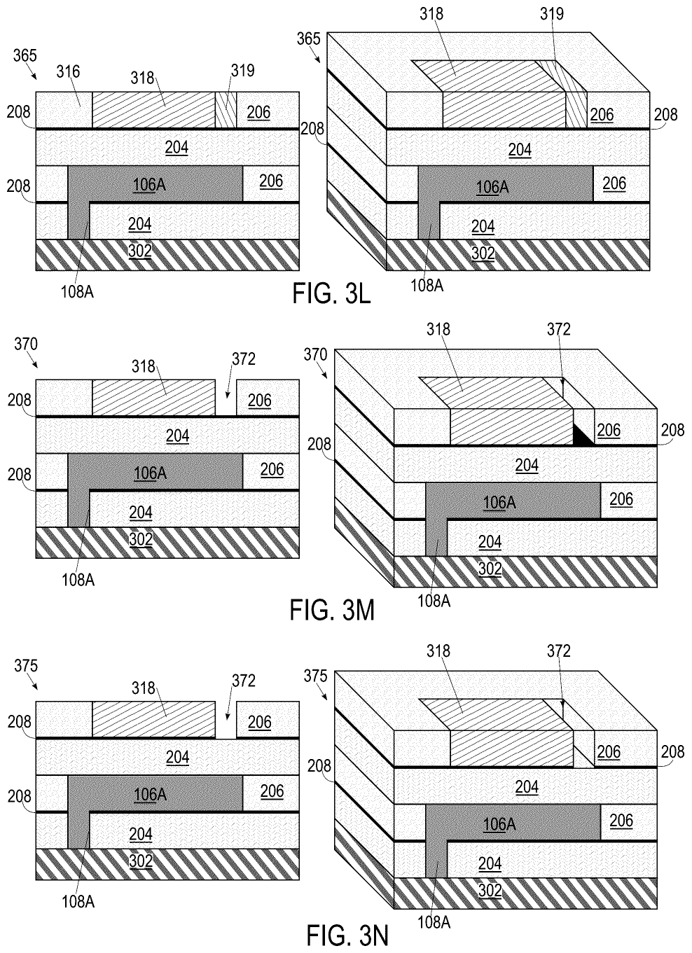

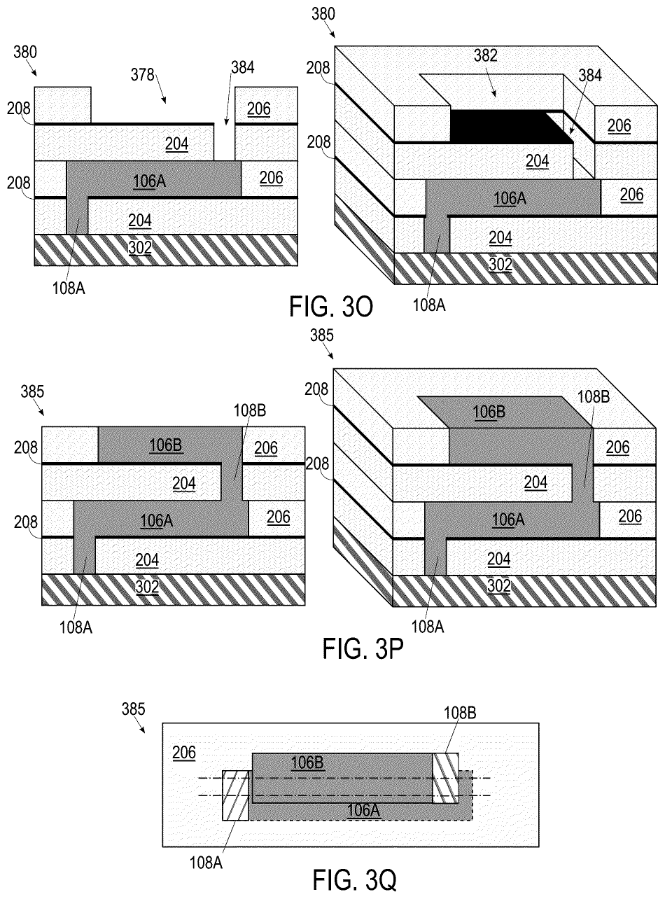

FIGS. 3A-3O are schematic cross-sectional views (left-hand side) and perspective views (right-hand side) of portions of microelectronic assembly 100 at various stages of manufacture according to some embodiments of the present disclosure. FIG. 3A shows a portion 300 of microelectronic assembly 100, in particular, a region around conductive vias 108A and 108B of FIG. 2 during an early stage of manufacture. A support structure 302 represents various buildup layers and or other features of package substrate 102 that are irrelevant to the operations described further and are therefore not shown in detail. Support structure 302 may comprise, by way of example and not as a limitation, the structure up to the surface of organic dielectric material 110 proximate to surface 118 of package substrate 102. In yet another example, structure 302 may comprise, by way of example and not as a limitation, the structure including portions of dielectric materials 104 over organic dielectric material 110. Other such configurations are possible within the broad scope of the embodiments. Of relevance is merely that positive-type photo-imageable dielectric 204 shown in FIG. 3A over support structure 302 represents any one layer 202 comprising such material and configured to include one or more conductive vias 108 rather than conductive traces 106 of package substrate 102. A seed layer 303 of copper or other metallic materials may be present over organic dielectric material 104, for example, to enhance adhesion of copper of conductive trace 106 in a subsequent process. Note that the size of support structure 302 may encompass a panel, a wafer, or an individual one of package substrate 102 without departing from the scope of the embodiments herein.

FIG. 3B shows a portion 305 subsequent to deposition of a layer of insulative material 208 over positive-type photo-imageable dielectric 204.

FIG. 3C shows a portion 310 subsequent to deposition of negative-type photo-imageable dielectric 206 over insulative material 208.

FIG. 3D shows a portion 315 subsequent to exposing negative-type photo-imageable dielectric 206 to three different electromagnetic energy levels to generate corresponding portions 316, 318 and 319 according to a desired pattern using a single mask based on the same fiducials. Portion 316 corresponds to a region which is not removed in a subsequent processing by any solvent such as a photoresist developer (i.e., it does not react with the photoresist developer); portion 318 corresponds to a region that requires more than one photoresist developer or solvent step for removal (i.e., it reacts moderately with the photoresist developer); and portion 319 corresponds to a region that is easily removable by the developer or solvent in subsequent processing (i.e., it reacts readily with the photoresist developer). Portion 318 corresponds to a pattern for a profile of conductive trace 106, portion 319 corresponds to a pattern and location for corresponding conductive via 108A, and portion 316 comprises the remainder.

With negative photoresists, such as negative-type photo-imageable dielectric 206, exposure to ultraviolet (UV) light causes the chemical structure of negative-type photo-imageable dielectric 206 to polymerize. As a result, the UV exposed negative photoresist, such as negative-type photo-imageable dielectric 206, remains on the surface while the photoresist developer removes the areas that are unexposed. In various embodiments, photoresist developers may be chosen based on the materials of positive-type photo-imageable dielectric 204 and/or negative-type photo-imageable dielectric 206 or based on other manufacturing criteria beyond the scope of the disclosure herein. Using greyscale exposure with different light energy levels, portion 316 is fully polymerized under a first dose of UV light corresponding to a first energy level, portion 318 is partially polymerized under a second dose of UV light corresponding to a second energy level and portion 319 is not polymerized at all under a third dose of UV light corresponding to a third energy level, the first energy level being higher than the second energy level, which is higher than the third energy level.

FIG. 3E shows a portion 320 subsequent to removal of portion 319 of negative-type photo-imageable dielectric 206 to generate a trench 322, exposing a portion of insulative material 208.

FIG. 3F shows a portion 325 subsequent to removal of exposed portion of insulative material 208 to extend trench 322 such that a surface of positive-type photo-imageable dielectric 204 is exposed underneath.

FIG. 3G shows a portion 330 subsequent to removing portion 318 of negative-type photo-imageable dielectric 206. The assembly comprising portion 330 is exposed to UV light, exposing portion 318 in negative-type photo-imageable dielectric 206. A portion of positive-type photo-imageable dielectric 204 under the gap in insulative material 208 in trench 322 is also exposed thereby. With positive photoresists, exposure to UV light makes the material more soluble in a photoresist developer. These exposed areas are then washed away with the photoresist developer solvent, creating trench 332 in negative-type photo-imageable dielectric 206 and trench 334 in positive-type photo-imageable dielectric 204. Thus, trenches 332 and 334 are produced substantially simultaneously (i.e., in a common operation) in such embodiments.

FIG. 3H shows a portion 340 subsequent to depositing (e.g., electroplating) conductive material of conductive trace 106 and conductive via 108 in trenches 332 and 334 respectively. The operations as described thus follow a dual damascene technique with trenches (corresponding to traces) and vias (hence dual or twice used) formed first, and into which conductive material such as copper is electroplated in a single operation. Because conductive trace 106 and conductive via 108 are formed in a common electroplating operation, they form a unitary structure undivided by any seam, interface, or other material. Further, because a profile or outline of conductive trace 106 was used to generate trenches 332 and 334 as described in reference to FIG. 3D, conductive via 108 is self-aligned with conductive trace 106, with zero-misalignment. Surfaces opposite to support structure 302 may be planarized in a planarizing operation, such as chemical mechanical polishing (CMP).

FIG. 3I shows a portion 350 subsequent to depositing a layer of positive-type photo-imageable dielectric 204 over negative-type photo-imageable dielectric 206 and conductive trace 106.

FIG. 3J shows a portion 355 subsequent to depositing a layer of insulative material 208 over positive-type photo-imageable dielectric 204 deposited as described in FIG. 3I.

FIG. 3K shows a portion 360 subsequent to depositing negative-type photo-imageable dielectric 206 over insulative material 208 deposited as described in FIG. 3J.

FIG. 3L shows a portion 365 subsequent to greyscale exposure of UV light (i.e., UV light at different energy levels) to generate different portions 316, 318 and 319 as described previously. Portion 318 corresponds to a pattern for a profile of another conductive trace 106B (whereas the previously labeled conductive trace 106 is now labeled as 106A in the figure to distinguish it from conductive trace 106B), and portion 319 corresponds to a pattern and location for corresponding conductive via 108B.

Because the pattern used to generate portions 316, 318 and 319 are independent of conductive trace 106A, in that the alignment of the pattern is based on fiducials and other markers independent of the process of forming conductive trace 106A, there is a non-zero likelihood of misalignment between the location of portion 319 and a desired location of conductive via 108B, leading to a potential for EPE 213 in excess of 0.1 micrometers. Further, because staggered via locations may be desired in some embodiments, the location of portion 319 may be displaced along the length of conductive trace 106A from conductive trace 108A.

FIG. 3M shows a portion 370 subsequent to removal of portion 319 of negative-type photo-imageable dielectric 206 to generate a trench 372, exposing a portion of insulative material 208.

FIG. 3N shows a portion 375 subsequent to removal of exposed portion of insulative material 208 to extend trench 372 such that a surface of positive-type photo-imageable dielectric 204 is exposed underneath.

FIG. 3O shows a portion 380 subsequent to removing portion 318 of negative-type photo-imageable dielectric 206. The assembly comprising portion 380 is exposed to UV light, exposing portion 318 in negative-type photo-imageable dielectric 206. A portion of positive-type photo-imageable dielectric 204 under the gap in insulative material 208 in trench 372 is also exposed thereby. These exposed areas are then washed away with the photoresist developer solvent, creating trench 382 in negative-type photo-imageable dielectric 206 and trench 384 in positive-type photo-imageable dielectric 204. Thus, trenches 382 and 384 are produced substantially simultaneously (i.e., in a common operation) in such embodiments.

FIG. 3P shows a portion 385 subsequent to depositing (e.g., electroplating) conductive material of conductive trace 106B and conductive via 108B in trenches 332 and 334 respectively.

FIG. 3Q shows a simplified plan view of portion 385 of FIG. 3P. Conductive traces 106A and 106B may not be aligned because of a likelihood of misalignment during the operations as described in FIG. 3L. Conductive via 108B may be self-aligned with conductive trace 106B, but not with conductive trace 106A for the reasons discussed therein. The operations as described herein may be repeated any number of times to generate package substrate 102 with staggered self-aligned vias.

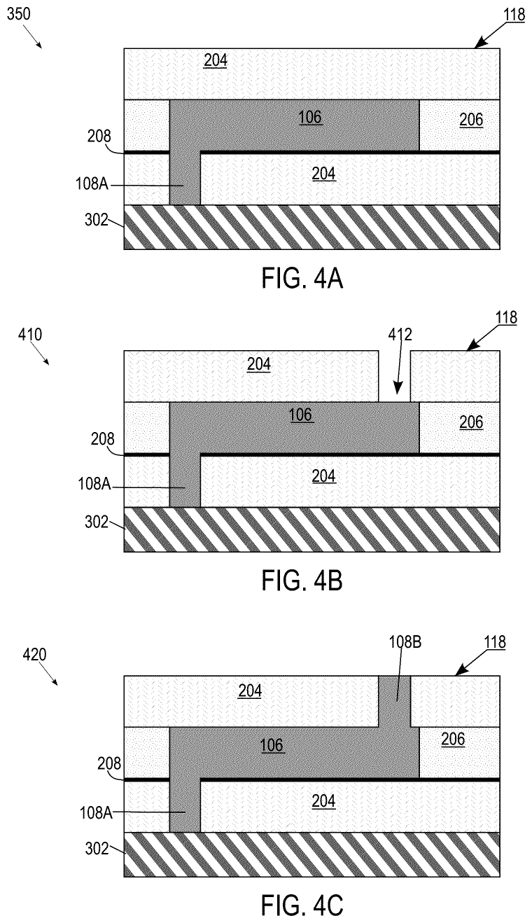

FIGS. 4A-4C are simplified cross-sectional views of a portion of package substrate at various stages of manufacture. FIG. 4A shows portion 350 of package substrate 102 subsequent to the operations as described in reference to FIG. 3I. In the particular embodiment shown in the figure, positive-type photo-imageable dielectric 204 on top of conductive trace 106 is proximate to surface 118 of package substrate 102. In some embodiments, the operations may be performed with package substrate 102 turned upside down, so that positive-type photo-imageable dielectric 204 on top of conductive trace 106 is proximate to surface 120 of package substrate 102.

FIG. 4B shows portion 410 subsequent to forming a via 412 in positive-type photo-imageable dielectric 204. In some embodiments, via 412 may be formed by conventional photolithography operations known in the art. In other embodiments, via 412 may be formed by laser drilling. In such embodiments, conductive via 108B may have EPE exceeding 0.1 micrometers because of the likelihood of misalignment in the laser drill pattern or the photolithography pattern relative to conductive trace 106, which is buried underneath positive-type photo-imageable dielectric 204.

FIG. 4C shows portion 420 subsequent to electroplating conductive via 108B in via 412, completing build up of package substrate 102 up to surface 118.

Although FIGS. 3-4 illustrate various operations performed in a particular order, this is simply illustrative, and the operations discussed herein may be reordered and/or repeated as suitable. Further, additional processes which are not illustrated may also be performed without departing from the scope of the present disclosure. Also, various ones of the operations discussed herein with respect to FIGS. 3-4 may be modified in accordance with the present disclosure to fabricate others of microelectronic assembly 100 disclosed herein. Although various operations are illustrated in FIGS. 3-4 once each, the operations may be repeated as often as desired. For example, one or more operations may be performed in parallel to manufacture and test multiple microelectronic assemblies substantially simultaneously. In another example, the operations may be performed in a different order to reflect the structure of a particular microelectronic assembly in which one or more substrates or other components as described herein may be included.

Furthermore, the operations illustrated in FIGS. 3-4 may be combined or may include more details than described. For example, the operations may be modified suitably without departing from the scope of the disclosure for IC dies that do not have a semiconductor substrate, but rather, are fabricated on other materials, such as glass or ceramic materials. Still further, the various operations shown and described may further include other manufacturing operations related to fabrication of other components of the microelectronic assemblies described herein, or any devices that may include the microelectronic assemblies as described herein. For example, the operations not shown in the figure may include various cleaning operations, additional surface planarization operations, operations for surface roughening, operations to include barrier and/or adhesion layers as desired, and/or operations for incorporating microelectronic assemblies as described herein in, or with, an IC component, a computing device, or any desired structure or device.

Example Devices and Components

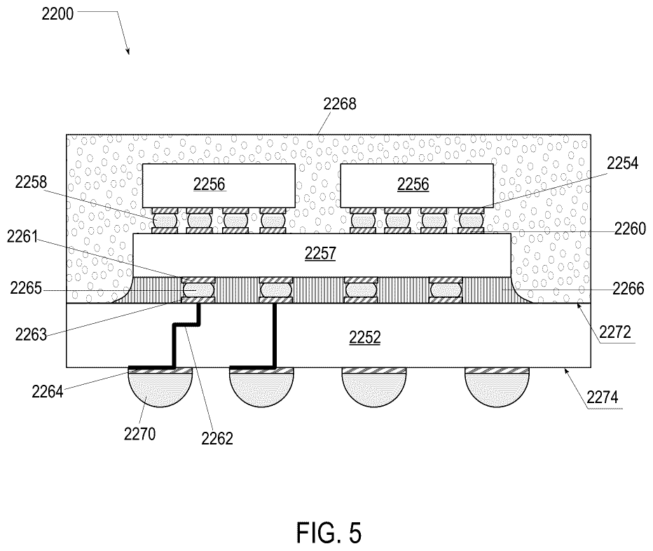

The packages disclosed herein, e.g., any of the embodiments shown in FIGS. 1-4 or any further embodiments described herein, may be included in any suitable electronic component. FIGS. 5-7 illustrate various examples of packages, assemblies, and devices that may be used with or include any of the IC packages as disclosed herein.

FIG. 5 is a side, cross-sectional view of an example IC package 2200 that may include IC packages in accordance with any of the embodiments disclosed herein. In some embodiments, the IC package 2200 may be a SIP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

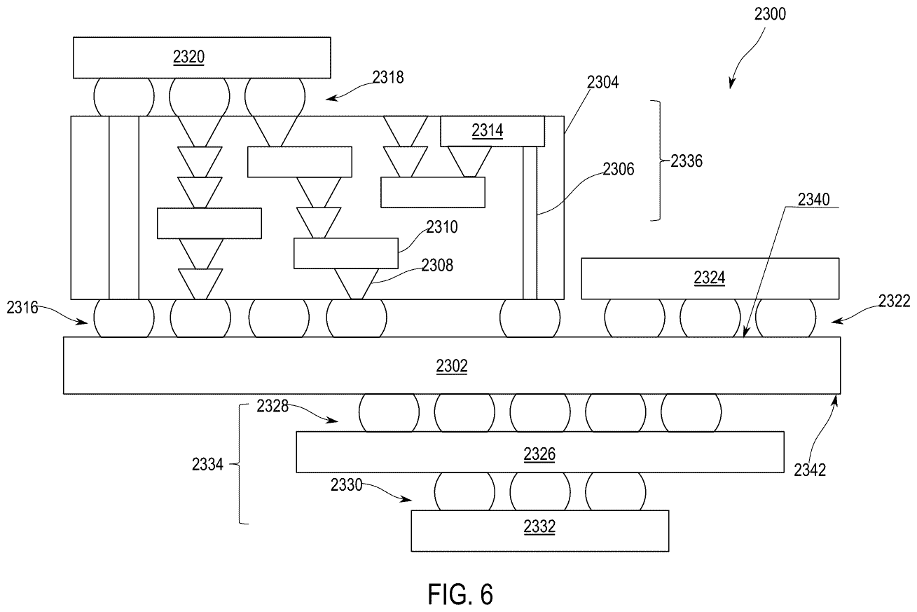

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 6.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 6 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 5.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 5. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

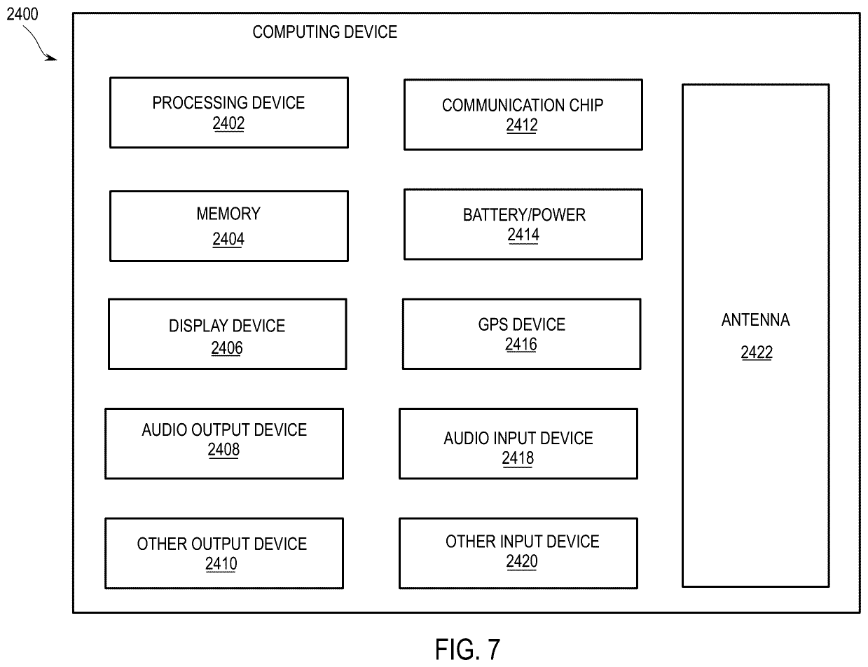

FIG. 7 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 5). In yet another example, any one or more of the components of computing device 2400 may include an IC device assembly 2300 (e.g., as shown in FIG. 6).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### SELECT EXAMPLES

Example 1 provides a package substrate, comprising: a conductive via (e.g., 108A) in a first layer (e.g., 202(1)), the first layer comprising a positive-type photo-imageable dielectric (204); a conductive trace (e.g., 106) in a second layer (e.g., 202(2)), the second layer comprising a negative-type photo-imageable dielectric (e.g., 206); and an insulative material (e.g., 208) between the first layer and the second layer, the insulative material configured to absorb electromagnetic radiation in a wavelength range between 10 nanometers and 800 nanometers, in which: the conductive via is directly attached to the conductive trace through the insulative material, the positive-type photo-imageable dielectric is soluble in a photoresist developer upon exposure to the electromagnetic radiation, and the negative-type photo-imageable dielectric is insoluble in the photoresist developer upon exposure to the electromagnetic radiation.

Example 2 provides the package substrate of example 1, in which: the conductive via is a first conductive via, the package substrate comprises a second conductive via (e.g., 108B) in a third layer (e.g., 202(3)), the third layer comprising the positive-type photo-imageable dielectric, the second layer of the conductive trace is between the first layer of the first conductive via and the third layer of the second conductive via, the second conductive via is directly attached to the conductive trace, and the first conductive via and the second conductive via are misaligned relative to each other along a length of the conductive trace.

Example 3 provides the package substrate of example 2, in which the first conductive via and the second conductive via are misaligned in a plane of the conductive trace and along a direction orthogonal to the length of the conductive trace.

Example 4 provides the package substrate of any one of examples 1-3, in which a first centerline of the conductive via is aligned with a second centerline of the conductive trace.

Example 5 provides the package substrate of any one of examples 1-4, in which the insulative material comprises at least one selected from carbon black, carbon nanotubes, anti-reflective nanorods, graphene, and THMMP.

Example 6 provides the package substrate of any one of examples 1-5, in which: the positive-type photo-imageable dielectric comprises at least one of polymethyl methacrylate (PMMA), diazoalkylquinone, diazobenzoquinone, or diazonaphtoquinone, and the negative-type photo-imageable dielectric comprises an epoxy resin.

Example 7 provides the package substrate of any one of examples 1-5, in which: the conductive via has a first width, the conductive trace has a second width, and the first width is substantially equal to the second width.

Example 8 provides the package substrate of any one of examples 1-7, in which sidewalls of the conductive via are not tapered.

Example 9 provides the package substrate of any one of examples 1-8, in which the conductive via and the conductive trace are not separated by any interface, seam, or material.

Example 10. The package substrate of any one of examples 1-9, further comprising: a first plurality of layers of the conductive vias surrounded by the positive-type photo-imageable dielectric; a second plurality of layers of the conductive trace surrounded by the negative-type photo-imageable dielectric; and a third plurality of layers of the insulative material between some of the first plurality of layers and the second plurality of layers, in which: individual layers in the first plurality of layers alternate with individual layers in the second plurality of layers, and the insulative material is at interfaces between the positive-type photo-imageable dielectric and the negative-type photo-imageable dielectric.

Example 11 provides a package substrate, comprising: a plurality of different dielectric materials in separate layers; a plurality of conductive vias in a first subset of the layers; and a plurality of conductive traces in a second subset of the layers, in which: individual ones of the first subset of the layers alternate with individual ones of the second subset of the layers, conductive vias in separate ones of the first subset of the layers, the conductive vias attached to a common conductive trace, are misaligned with respect to each other in a direction along a length of the conductive trace, and centers of a subset of conductive vias in a first layer in the first subset of layers are aligned with corresponding centerlines of conductive traces in a second layer in the second subset of layers, the first layer being adjacent to the second layer, the subset of conductive vias being coupled directly to the corresponding conductive traces.

Example 12 provides the package substrate of example 11, in which the different dielectric materials include: a positive-type photo-imageable dielectric, a negative-type photo-imageable dielectric, and an insulative material capable of absorbing light or ultraviolet light.

Example 13 provides the package substrate of example 12, in which the positive-type photo-imageable dielectric comprises at least one of PMMA, diazoalkylquinone, diazobenzoquinone, or diazonaphtoquinone.

Example 14 provides the package substrate of example 12, in which the negative-type photo-imageable dielectric comprises an epoxy resin.

Example 15 provides the package substrate of example 12, in which the insulative material is at least one of: carbon black, carbon nanotubes, anti-reflective nanorods, graphene, and THMMP.

Example 16 provides the package substrate of any one of examples 11-15, in which respective centerlines of the conductive vias in separate ones of the first subset of the layers and coupled to a common conductive trace are misaligned with respect to each other in a direction along a width of the conductive trace.

Example 17 provides the package substrate of any one of examples 11-16, further comprising an IC die embedded in the package substrate.

Example 18 provides the package substrate of example 17, in which: a third subset of the layers comprises an epoxy-based organic dielectric material, and the IC die is embedded in the third subset of the layers.

Example 19 provides the package substrate of example 18, further comprising TDVs in the epoxy-based organic dielectric material.

Example 20 provides the package substrate of any one of examples 17-19, in which the first subset of the layers and the second subset of the layers are between the IC die and a surface (e.g., 118) of the package substrate.

Example 21 provides a microelectronic assembly, comprising: a plurality of IC dies (e.g., 116); and a package substrate coupled to the plurality of IC dies, in which: the package substrate comprises: a bridge IC die surrounded by an epoxy-based dielectric material; conductive traces in negative-type photo-imageable dielectric; conductive vias in positive-type photo-imageable dielectric; and an insulative material capable of absorbing electromagnetic radiation in a wavelength range between 10 nanometers and 800 nanometers at a subset of interfaces between the negative-type photo-imageable dielectric and positive-type photo-imageable dielectric.

Example 22 provides the microelectronic assembly of example 21, in which: a first conductive via in the package substrate is coupled to a conductive trace in the package substrate, a second conductive via in the package substrate is coupled to the conductive trace, the first conductive via and the second conductive via are displaced with respect to each other along a length of the conductive trace.

Example 23 provides the microelectronic assembly of example 22, in which: the first conductive via and the second conductive via are displaced with respect to each other along a width of the conductive trace.

Example 24 provides the microelectronic assembly of example 23, in which: the first conductive via and the second conductive via have respective widths that are substantially similar to the width of the conductive trace.

Example 25 provides the microelectronic assembly of any one of examples 22-24, in which: the first conductive via is aligned with the conductive trace, and the insulative material is between the positive-type photo-imageable dielectric surrounding the first conductive via and the negative-type photo-imageable dielectric surrounding the conductive trace.

Example 26 provides the microelectronic assembly of any one of examples 22-25, in which: the second conductive via is not aligned with the conductive trace, and the insulative material is not between the positive-type photo-imageable dielectric surrounding the second conductive via and the negative-type photo-imageable dielectric surrounding the conductive trace.

Example 27 provides the microelectronic assembly of any one of examples 21-26, in which the bridge IC die comprises conductive pathways conductively coupling two or more IC dies in the plurality of IC dies.

Example 28 provides the microelectronic assembly of any one of examples 21-26, in which the bridge IC die comprises TSVs.

Example 29 provides the microelectronic assembly of any one of examples 21-28, further comprising a motherboard coupled to a side of the package substrate opposite to the plurality of IC dies.

Example 30 provides the microelectronic assembly of any one of examples 21-29, in which the plurality of IC dies is coupled to the package substrate by interconnects having a pitch of less than 18 micrometers between adjacent interconnects.

Example 31 provides a method, comprising: providing a support structure; depositing a positive-type photo-imageable dielectric in a first layer over the support structure; depositing an insulative material over the positive-type photo-imageable dielectric, the insulative material being capable of absorbing electromagnetic radiation having wavelength in a range between 10 nanometers and 800 nanometers; depositing a negative-type photo-imageable dielectric in a second layer over the insulative material; forming a first trench in the negative-type photo-imageable dielectric, the first trench corresponding to a profile of a conductive trace; forming a second trench in the positive-type photo-imageable dielectric, the second trench corresponding to the conductive via; and depositing conductive material in the first trench and the second trench, forming the conductive trace and connected conductive via respectively.

Example 32 provides the method of example 31, further comprising: before forming the first trench, forming a third trench in the negative-type photo-imageable dielectric, the third trench corresponding to the profile of the conductive via, the trench exposing a portion of the insulative material.

Example 33 provides the method of example 32, in which forming the third trench comprises: exposing the negative-type photo-imageable dielectric to three different levels of electromagnetic radiation energy levels comprising a first energy level, a second energy level and a third energy level, in which: a first portion of the negative-type photo-imageable dielectric exposed to the first energy level is configured to not react with a photoresist developer, a second portion of the negative-type photo-imageable dielectric exposed to the second energy level is configured to react moderately with the photoresist developer, a third portion of the negative-type photo-imageable dielectric exposed to the third energy level is configured to react readily with a photoresist developer; and removing the third portion of the negative-type photo-imageable dielectric with the photoresist developer.

Example 34 provides the method of example 33, in which the electromagnetic radiation energy is exposed through a patterned mask comprising respective profiles of the conductive trace and the conductive via.

Example 35 provides the method of any one of examples 33-34, in which forming the first trench comprises removing the second portion of the negative-type photo-imageable dielectric with the photoresist developer.

Example 36 provides the method of any one of examples 32-34, further comprising: removing the portion of the insulative material, exposing a portion of the positive-type photo-imageable dielectric.

Example 37 provides the method of example 36, in which forming the second trench comprises dry etching the portion of the positive-type photo-imageable dielectric.

Example 38 provides the method of any one of examples 31-37, further comprising: repeating the depositing the positive-type photo-imageable dielectric, depositing the insulative material, depositing the negative-type photo-dielectric material, forming the first trench, forming the second trench, and depositing the conductive material until a desired number of layers of the positive-type photo-imageable dielectric alternating with the negative-type dielectric is obtained with the conductive vias in the positive-type photo-imageable dielectric and the conductive traces in the negative-type photo-imageable dielectric, in which conductive vias attached to conductive traces in a region proximate to the insulative material are self-aligned to the corresponding conductive traces.

Example 39 provides the method of any one of examples 31-38, further comprising: depositing the positive-type photo-imageable dielectric in a third layer over the negative-type photo-imageable dielectric; and forming another conductive via in the third layer, the another conductive via directly coupled to the conductive trace.

Example 40 provides the method of example 39, in which forming the conductive via comprises: laser drilling a third trench according to a pattern corresponding to a profile of the another conductive via; and depositing the conductive material in the third trench.

Example 41 provides the microelectronic assembly of example 21, in which the microelectronic assembly is part of a computing device, and the computing device includes at least one of: a processing device, a memory, a communication chip, a display device and an output device.

Example 42 provides the package substrate of example 11, in which the package substrate is part of a computing device, and the computing device comprises at least one of a processor device, a memory, and a display.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A package substrate, comprising:
a conductive via in a first layer, the first layer comprising a positive-type photo-imageable dielectric;
a conductive trace in a second layer, the second layer comprising a negative-type photo-imageable dielectric; and
an insulative material between the first layer and the second layer, the insulative material configured to absorb electromagnetic radiation in a wavelength range between 10 nanometers and 800 nanometers,
wherein:
the conductive via is directly attached to the conductive trace through the insulative material,
the positive-type photo-imageable dielectric is soluble in a photoresist developer upon exposure to the electromagnetic radiation, and
the negative-type photo-imageable dielectric is insoluble in the photoresist developer upon exposure to the electromagnetic radiation.

2. The package substrate of claim 1, wherein:
the conductive via is a first conductive via,
the package substrate comprises a second conductive via in a third layer, the third layer comprising the positive-type photo-imageable dielectric,
the second layer of the conductive trace is between the first layer of the first conductive via and the third layer of the second conductive via,
the second conductive via is directly attached to the conductive trace, and
the first conductive via and the second conductive via are misaligned relative to each other along a length of the conductive trace.

3. The package substrate of claim 2, wherein the first conductive via and the second conductive via are misaligned in a plane of the conductive trace and along a direction orthogonal to the length of the conductive trace.

4. The package substrate of claim 1, wherein a first centerline of the conductive via is aligned with a second centerline of the conductive trace.

5. The package substrate of claim 1, wherein the insulative material comprises at least one selected from carbon black, carbon nanotubes, anti-reflective nanorods, graphene, and transferable hyperbolic metamaterial particles (THM MP).

6. The package substrate of claim 1, wherein:
the conductive via has a first width,
the conductive trace has a second width, and
the first width is substantially equal to the second width.

7. The package substrate of claim 1, further comprising:
a first plurality of layers of conductive vias surrounded by the positive-type photo-imageable dielectric;
a second plurality of layers of conductive trace surrounded by the negative-type photo-imageable dielectric; and
a third plurality of layers of the insulative material between some of the first plurality of layers and the second plurality of layers,
wherein:
individual layers in the first plurality of layers alternate with individual layers in the second plurality of layers, and
the insulative material is at interfaces between the positive-type photo-imageable dielectric and the negative-type photo-imageable dielectric.

8. A package substrate, comprising:
a plurality of different dielectric materials in separate layers;
a plurality of conductive vias in a first subset of the layers; and
a plurality of conductive traces in a second subset of the layers,
wherein:
individual ones of the first subset of the layers alternate with individual ones of the second subset of the layers,
conductive vias in separate ones of the first subset of the layers, the conductive vias attached to a common conductive trace, are misaligned with respect to each other in a direction along a length of the conductive trace, and
centers of a subset of conductive vias in a first layer in the first subset of layers are aligned with corresponding centerlines of conductive traces in a second layer in the second subset of layers, the first layer being adjacent to the second layer, the subset of conductive vias being coupled directly to the corresponding conductive traces.

9. The package substrate of claim 8, wherein the different dielectric materials include: a positive-type photo-imageable dielectric, a negative-type photo-imageable dielectric, and an insulative material capable of absorbing light or ultraviolet light.

10. The package substrate of claim 9, wherein the positive-type photo-imageable dielectric comprises polymethyl methacrylate (PM MA).

11. The package substrate of claim 9, wherein the negative-type photo-imageable dielectric comprises an epoxy material.

12. The package substrate of claim 8, wherein:
the package substrate is part of a computing device, and
the computing device comprises at least one of a processor device, a memory, and a display.

13. The package substrate of claim 8, wherein respective centerlines of the conductive vias in separate ones of the first subset of the layers and coupled to a common conductive trace are misaligned with respect to each other in a direction along a width of the conductive trace.

14. A microelectronic assembly, comprising:
a plurality of IC dies; and
a package substrate coupled to the plurality of IC dies,
wherein:
the package substrate comprises:
a bridge IC die surrounded by an epoxy-based dielectric material;
conductive traces in negative-type photo-imageable dielectric;
conductive vias in positive-type photo-imageable dielectric; and
an insulative material capable of absorbing electromagnetic radiation in a wavelength range between 10 nanometers and 800 nanometers at a subset of interfaces between the negative-type photo-imageable dielectric and positive-type photo-imageable dielectric.

15. The microelectronic assembly of claim 14, wherein:
a first conductive via in the package substrate is coupled to a conductive trace in the package substrate,
a second conductive via in the package substrate is coupled to the conductive trace,
the first conductive via and the second conductive via are displaced with respect to each other along a length of the conductive trace.

16. The microelectronic assembly of claim 15, wherein: the first conductive via and the second conductive via are displaced with respect to each other along a width of the conductive trace.

17. The microelectronic assembly of claim 16, wherein: the first conductive via and the second conductive via have respective widths that are substantially similar to the width of the conductive trace.

18. The microelectronic assembly of claim 15, wherein:
the first conductive via is aligned with the conductive trace, and
the insulative material is between the positive-type photo-imageable dielectric surrounding the first conductive via and the negative-type photo-imageable dielectric surrounding the conductive trace.

19. The microelectronic assembly of claim 15, wherein:
the second conductive via is not aligned with the conductive trace, and
the insulative material is not between the positive-type photo-imageable dielectric surrounding the second conductive via and the negative-type photo-imageable dielectric surrounding the conductive trace.

20. The microelectronic assembly of claim 14, wherein:
the microelectronic assembly is part of a computing device, and
the computing device includes at least one of: a processing device, a memory, a communication chip, a display device and an output device.
